(19) United States
(12) Patent Application Publication
(10) Pub. No.: US 2025/0293202 A1
(43) Pub. Date: Sep. 18, 2025

(54) RESIN COMPOSITION AND METHOD OF FORMING A SEMICONDUCTOR PACKAGE WITH UNDERFILL USING THE SAME

(71) Applicant: Samsung Electronics Co., Ltd., Suwon-si (KR)

(72) Inventors: Taehyung Lee, Suwon-si (KR); Joonhyeok Jang, Suwon-si (KR)

(21) Appl. No.: 18/893,153

(22) Filed: Sep. 23, 2024

(30) Foreign Application Priority Data
Mar. 15, 2024 (KR) 10-2024-0036120

(51) Int. Cl. H01L 23/00

(52) U.S. Cl. CPC H01L 24/83; H01L 24/29; H01L 24/32; H01L 24/81; H01L 24/92; H01L 24/16; H01L 24/73; H01L 2224/16157; H01L 2224/2929; H01L 2224/32013; H01L 2224/32225; H01L 2224/73204; H01L 2224/81986; H01L 2224/83104; H01L 2224/83224; H01L 2224/92125

(57) ABSTRACT

A method of manufacturing a semiconductor package that includes mounting a semiconductor chip on a substrate, dispensing a resin composition to a first side of the semiconductor chip, in which the resin composition includes a filling portion flowing to an inside region of the semiconductor chip between the semiconductor chip and the substrate, and an outside portion flowing outside the semiconductor chip; and projecting infrared light onto at least a portion of the outside portion of the resin composition, while the resin composition flows to an opposite side of the semiconductor chip that is opposite from the first side of the semiconductor, wherein the resin composition includes 20 to 40 10 wt % of an epoxy resin, 5 to 10 wt % of a curing agent, 50 to 70 wt % of a filler, and 1 to 5 wt % of an infrared absorber.

### CROSS-REFERENCE TO RELATED APPLICATIONS

This U.S. non-provisional application claims the benefit of priority under 35 U.S.C. § 119 to Korean Patent Application No. 10-2024-0036120 filed on Mar. 15, 2024, in the Korean Intellectual Property Office, the disclosure of which is incorporated herein by reference in its entirety.

### BACKGROUND

The present inventive concept relates to a resin composition, a method of forming underfill using the same, and a method of manufacturing a semiconductor package using the same.

As the bump pitch of semiconductor chips has recently become smaller, there is a need for development to improve the fluidity and filling properties of underfill materials injected between a substrate and a semiconductor chip. If the viscosity of underfill materials is low, fluidity and filling properties may be improved, but underfill materials may flow to the outside of the semiconductor chip and cause various defects.

### SUMMARY

An aspect of the present inventive concept is to provide a method of controlling flow of underfill and forming underfill with improved reliability.

According to an aspect of the present inventive concept, a method of forming underfill or manufacturing a semiconductor package includes: mounting a semiconductor chip on a substrate; dispensing a resin composition to a first side of the semiconductor chip in which the resin composition includes a filling portion flowing to an inside region of the semiconductor chip between the semiconductor chip between the semiconductor chip and the substrate, and an outside portion flowing outside of the semiconductor chip; and projecting infrared light onto at least a portion of the outside portion of the resin composition, while the resin composition flows to an opposite side of the semiconductor chip that is opposite from the first side of the semiconductor chip, in which the resin composition includes 20 to 40 wt % of an epoxy resin; 5 to 10 wt % of a curing agent; 50 to 70 wt % of a filler; and 1 to 5 wt % of an infrared absorber.

According to an aspect of the present inventive concept, a method of forming underfill or method of manufacturing a semiconductor package includes: mounting a semiconductor chip on a substrate; dispensing a resin composition including an infrared absorber to a first side of the semiconductor chip between the semiconductor chip and the substrate, and out outside portion flowing outside the semiconductor chip, in which the resin composition includes a filling portion flowing to an inside region of the semiconductor chip between the semiconductor chip and the substrate, and an outside portion flowing to a region outside of the semiconductor chip; and projecting infrared light onto at least a portion of the resin composition, while the resin composition flows between the semiconductor chip and the substrate from the first side of the semiconductor chip, in which the outside portion includes a first outside portion adjacent to a first side surface of the semiconductor chip corresponding to the first side of the semiconductor chip and a second outside portion adjacent to a second side surface of the semiconductor chip, intersecting the first side surface, in which the infrared light is projected onto the second outside portion, and in which a second width of the second outside portion is smaller than a first width of the first outside portion.

According to an aspect of the present inventive concept, a resin composition includes: 20 to 40 wt % of an epoxy resin; 5 to 10 wt % of a curing agent; 50 to 70 wt % of a filler; and 1 to 5 wt % of an infrared absorber including a compound having at least one structure selected from Chemical formula 1, Chemical formula 2, Chemical formula 3, and Chemical formula 4 below,

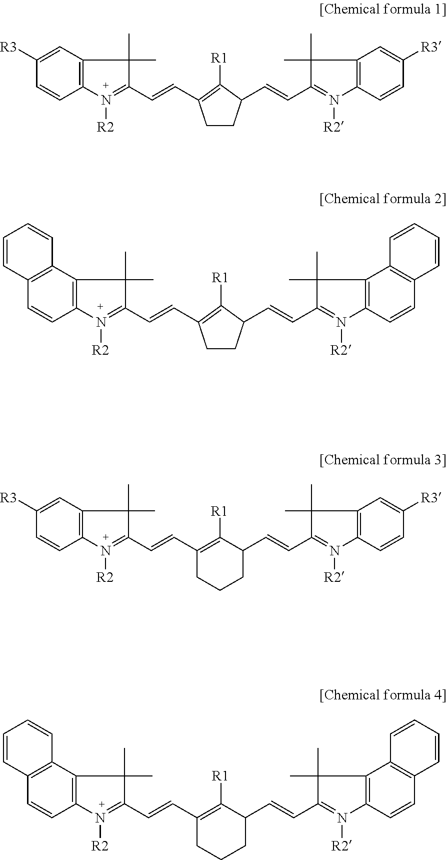

(wherein R1 includes a barbiturate group, R2 and R2′ include at least one group selected from a methyl group, an ethyl group, and a 3-methylbutyl group, and R3 and R3′ include hydrogen or chlorine).

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a flowchart illustrating a method of forming underfill according to an example embodiment of the present inventive concept;

FIGS. 2A and 2B are diagrams illustrating an operation of mounting a semiconductor chip according to an example embodiment;

FIGS. 3A and 3B are diagrams illustrating an operation of dispensing a resin composition according to an example embodiment;

FIGS. 4A and 4B are diagrams illustrating an operation of projecting infrared light according to an example embodiment;

FIGS. 5A and 5B are diagrams illustrating an operation of projecting infrared light according to an example embodiment;

FIGS. 6A and 6B are diagrams illustrating an operation of projecting infrared light according to an example embodiment;

FIG. 7 is a diagram illustrating an operation of projecting infrared light according to an example embodiment; and

FIGS. 8 to 10 are diagrams illustrating an operation of curing a resin composition according to an example embodiment.

### DETAILED DESCRIPTION

Embodiments of the present inventive concept will be described herein with reference to the attached drawings.

Unless otherwise specified, in this specification, terms, such as ‘upper pad,’ ‘lower pad,’ ‘side surface,’ etc. are based on the drawings, and may vary in the directions in which components are actually arranged.

In addition, ordinal numbers, such as “first,” “second,” “third,” etc. may be used as labels for specific elements, steps, directions, etc. to distinguish various elements, steps, directions, etc. from each other, and are not meant to be limiting. Terms that are not described using “first,” “second,” etc. in the specification may still be referred to as “first” or “second” in the claims. In addition, terms referenced by a particular ordinal number (e.g., “first” in a particular claim) may be described elsewhere with a different ordinal number (e.g., “second” in the specification or other claims).

It will be understood that the terms “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

As used herein, the term “and/or” includes any and all combinations of one or more of the associated listed items and may be abbreviated as “/”. Items described in the singular herein may be provided in plural, as can be seen, for example, in the drawings. Thus, the description of a single item that is provided in plural should be understood to be applicable to the remaining plurality of items unless context indicates otherwise.

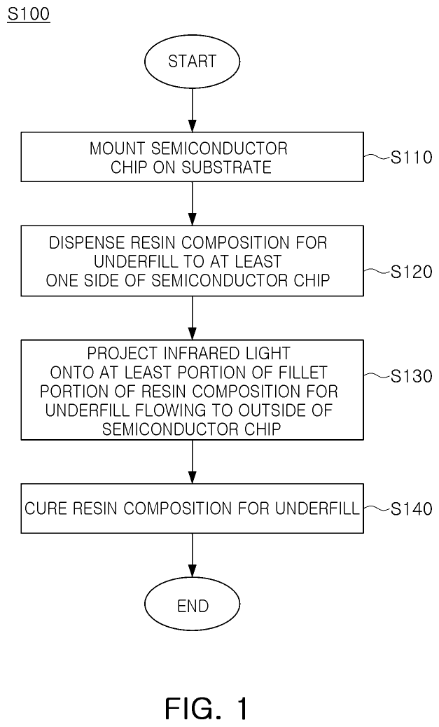

FIG. 1 is a flowchart illustrating an underfill forming method (S100) according to an example embodiment of the present inventive concept.

Referring to FIG. 1, the underfill forming method (S100) of an example embodiment may include mounting a semiconductor chip on a substrate (S110); dispensing a resin composition to at least a first side of a semiconductor chip (S120); and projecting infrared light onto at least a portion of the resin composition (S130). According to an embodiment, the underfill forming method (S100) of an example embodiment may further include curing the resin composition (S140). The curing may take place for example, after the resin composition flows to the opposite side of the semiconductor chip from the first side, to form an underfill resin layer. Flow of the resin composition from a first side to an opposite side may include the resin flowing to the end of the opposite side, but may also include resin flowing past the end of the opposite side or flowing not be completely to the opposite side.

In example embodiments, the steps shown in FIG. 1, may overlap in time with one another and the present methods are not limited to methods in which the steps take place in discrete time periods that do not overlap with one another. For example, S120 (dispensing resin) and S130 (projecting IR light) may overlap in time; and S130 (projecting IR light) and S140 (curing resin) may overlap in time, as described further herein.

The underfill forming method (S100) of an example embodiment may use a resin composition configured to convert light in an infrared region into thermal energy.

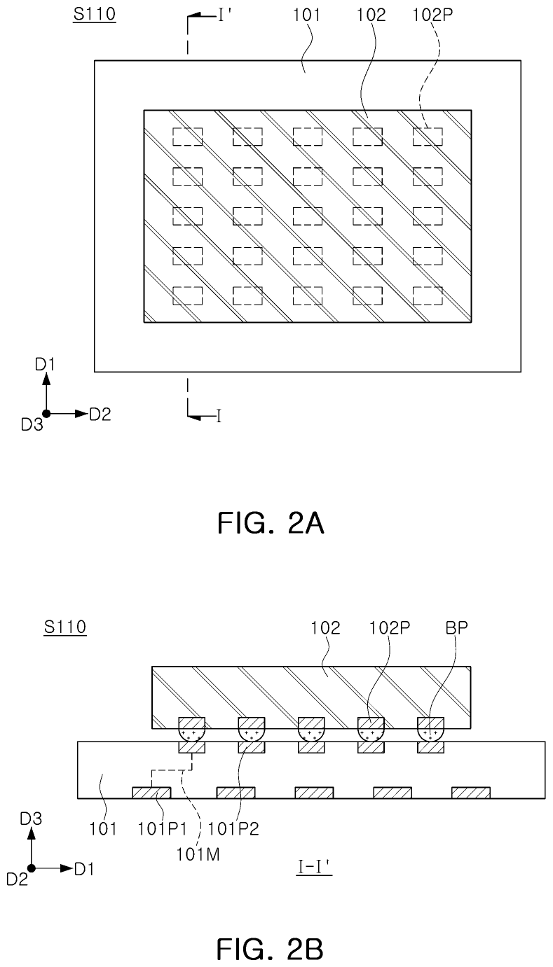

The resin composition of an example embodiment may include an epoxy resin, a curing agent, a filler, and an infrared absorber. According to an embodiment, the resin composition may further include an additive. The resin composition described herein may be understood as being applied to the resin composition 103 shown in FIGS. 2A to 10. Resin compositions described herein may be used to form underfill in the various embodiments herein.

The epoxy resin may include at least one epoxy component selected from the group consisting of a bisphenol-A epoxy, a bisphenol-F epoxy, rubber modified epoxy, novolac epoxy, cycloaliphatic epoxy, tetra-functional epoxy, acryl modified epoxy, coal tar modified epoxy, aliphatic chain modified epoxy, cresol novolac epoxy, polyglycol epoxy, cardanol epoxy, brominated epoxy, and phenoxy epoxy. The epoxy resin may be included in 20 wt % to 40 wt % of the total composition.

The curing agent may include at least one curing agent selected from the group consisting of an acid anhydride-based curing agent, a cationic curing agent, an imidazole curing agent, a dicyandiamide curing agent, and an amine adduct curing agent. The curing agent may be included in 5 wt % to 10 wt % of the total composition.

The acid anhydride-based curing agent may include at least one curing agent selected from the group consisting of dodecenyl succinic anhydride (DDSA), polyadipic acid (PADA), polysebacic acid (PSPA), methyl tetrahydrophthalic anhydride (Me-THPA), methyl hexahydrophthalic anhydride (Me-HHPA), methylhymic anhydride (MHAC), tetrahydrophthalic anhydride (THPA), phthalic anhydride (PA), trimethylicanhydride (TMA), pyromethylic anhydride (PMDA), benzophenon tetracarboxylic anhydride (BTDA), chlorendicanhydride (HET), and tetrabromo phthalic anhydride (TBPA).

The cationic curing agent may include at least one selected from the group consisting of [4-(acetyloxy)phenyl]dimethylsulfonium(OC-6-11)-hexafluoroantimonate (1-), PC-2508, CXC-1742, CXC-1751, N-benzylpyrazinium hexafluoroantimonate (BPH), XNA-2201, and XNA-2202.

The imidazole curing agent may include at least one selected from the group consisting of 2-methylimidazole, 2-ethyl-4-methylimidazole, 2-undecylimidazole, 2-heptadecylimidazole, 2-phenylimidazole, 2-phenyl-4-methylimidazole, 1-benzyl-2-methylimidazole, 2-ethylimidazole, 2-isopropylimidazole, 2-phenyl-4-benzylimidazole, 1-cyanoethyl-2-methylimidazole, 1-cyanoethyl-2-ethyl-4-methylimidazole, 1-cyanoethyl-2-undecylimidazole, 1-cyanoethyl-2-isopropylimidazole, 1-cyanoethyl-2- phenylimidazole, 1-cyanoethyl-2-methylimidazole-trimellitate, 1-cyanoethyl-2-ethyl-4-methylimidazole-trimellitate, 1-cyanoethyl-2-undecylimidazole-trimellitate, 1-cyanoethyl-2- undecylimidazole-trimellitate, 1-cyanoethyl-2-phenylimidazole-trimellitate, 2,4-diamino-6-(2′-methylimidazole-(1′))-ethyl-S-triazine, 2,4-diamino-6-(2′-ethyl-4-methylimidazoly-(1′))-ethyl-S-triazine),2,4-diamino-6-(2′-undecylimidazole-(1′))-ethyl-S-triazine, 2-methylimidazole-isocyanuric acid addition compound, 2-phecylimidazole-isocyanuricacid addition compound, 2,4-diamino-6-(2′-methylimidazole-(1′))-ethyl-S-triazineisocyanuric adduct, 2-phecyl-4,5-dihydroxymethylimidazole, 2-phecyl-4-methyl-5-hydroxymethyl, 2-phecyl-4-benzyl-5-hydroxymethyl imidazole, 4.4′-methylene-bis-(2-ethyl-5-methylimidazole, and 1-cyanoethyl-2-phenyl-4,5-di(cyanoethoxymethyl)imidazole).

The filler may include an inorganic filler. The filler may include fused silica or synthetic silica. The filler may be included in an amount of 50 wt % to 70 wt % of the total composition. If the filler is less than 50 wt %, physical properties, such as strength and thermal expansion coefficient, may be reduced. If the filler exceeds 70 wt %, the fluidity of the resin composition may decrease.

The infrared absorber may be configured to, or may be capable of absorbing infrared light having a wavelength ranging from 700 nm to 1200 nm, 700 nm to 1000 nm, or 700 nm to 900 nm and converting absorbed light into thermal energy. The infrared absorber may be included in an amount of 1% to 5 wt % of the total composition. If the infrared absorber is less than 1 wt %, the effect of controlling the temperature and viscosity of a fillet portion of the resin composition may be reduced. If the infrared absorber exceeds 5 wt %, the high temperature and/or high moisture reliability of the resin composition may be reduced.

The infrared absorber may include at least one functional group of R1, R2, R2,′ R3, and R3,′ and may include a compound having a heptamethine cyanine structure including cyclopentene and cyclohexene structures. For example, the infrared absorber may be expressed by at least one of the structures of [Chemical formula 1], [Chemical formula 2], [Chemical formula 3], and [Chemical formula 4], but is not limited thereto. R1 may include a barbiturate group having the structure of [Chemical formula 5], [Chemical formula 6], or [Chemical formula 7], R2 and R2′ may include at least one of a methyl group, an ethyl group, and a 3-methylbutyl group (e.g., CH₂CH₂CH(CH₃)₂), and R3 and R3′ may include hydrogen or chlorine, but are not limited thereto.

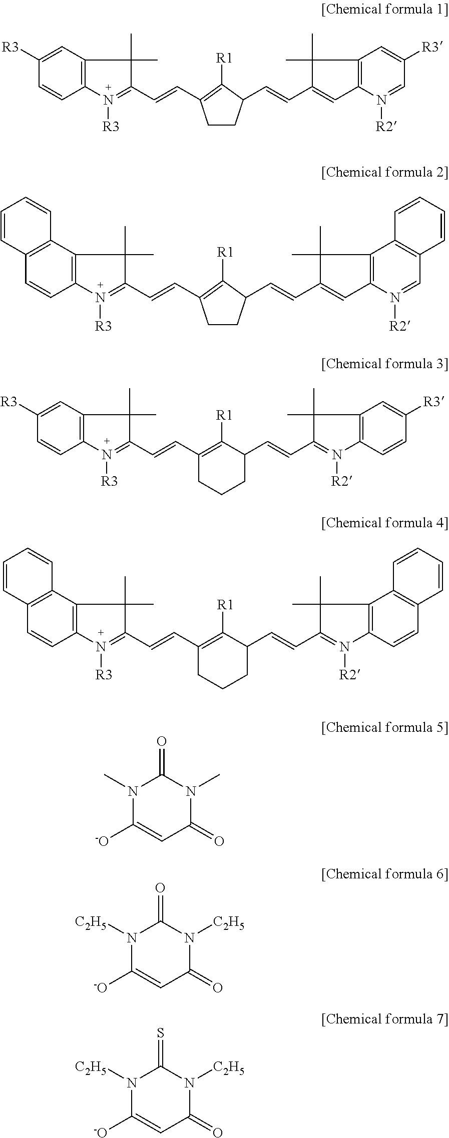

The additive may include pigment, dye, a leveling agent, a defoaming agent, an adhesion promoter, a coupling agent, a softener, or the like. The additive may exceed 0% and may be 5 wt % or less of the total composition.

### Experiment Example

According to example embodiments, as described above, the temperature of the resin composition may be locally increased and the viscosity and flow of the resin composition flowing to the outside of the semiconductor chip may be controlled by projecting infrared light onto the resin composition including an infrared absorber.

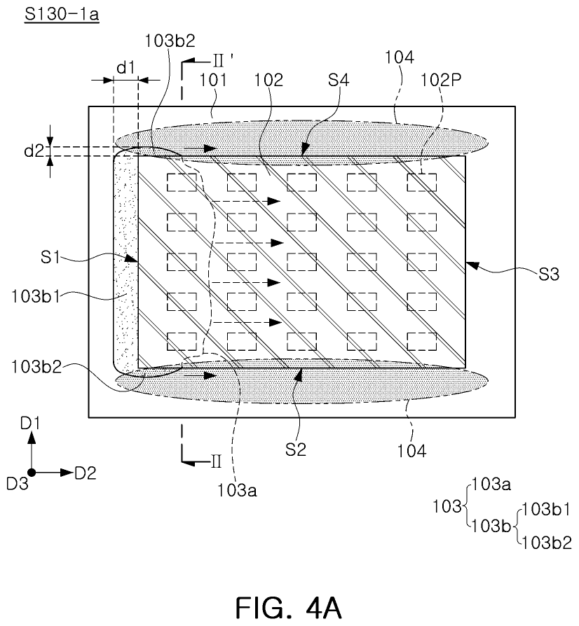

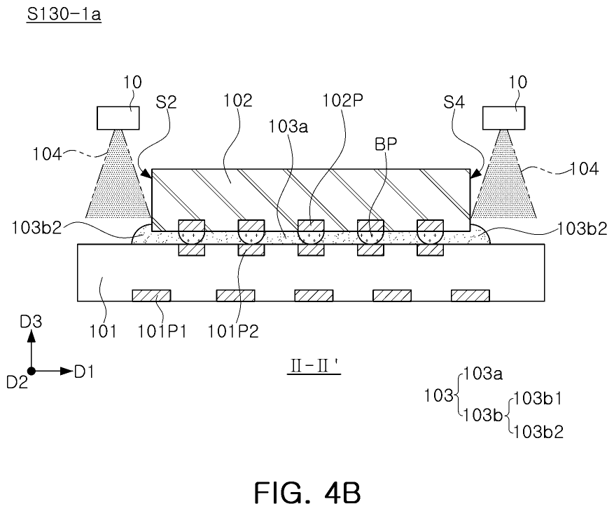

For example, infrared light may be projected onto a fillet portion (‘103b’ in FIGS. 4A, 5A, 6A, and 7) of the resin composition flowing to the outside of the semiconductor chip, and as a result, the temperature of the fillet portion (FIGS. 4A, 5A, 6A, and 7) may be increased to 100° C. or higher and the viscosity of the fillet portion (‘103b’ in FIGS. 4A, 5A, 6A, and 7) may be increased to 80 mPas (based on 100° C.) or more. That is, according to example embodiments, by suppressing the outward flow of the resin composition, resultant defects may be prevented.

A portion of the resin composition that extends past an edge (outside the footprint) of the semiconductor chip may be referenced herein as an outside portion or a fillet portion.

When infrared light is “projected onto a fillet portion,” or onto a first fillet portion or onto a second fillet portion, it should be understood that infrared light may be projected onto a portion of the fillet, or the whole fillet, and is not meant to be limiting unless specified as such.

According to example embodiments, after infrared light is projected onto at least a portion of the fillet portion, a first temperature of the fillet portion is higher than a second temperature of the filling portion. According to further embodiments, a viscosity of the fillet portion onto which the infrared light is projected may be higher than a viscosity of the filling portion.

Hereinafter, a method of manufacturing including the underfill forming method (S100) according to an example embodiment is described in detail with reference to FIGS. 2A to 10. The method may be used to manufacture a semiconductor device, such as a semiconductor package. After forming the underfill, additional steps may be performed such as adding additional semiconductor chips to the package and encasing the package in a molding compound.

FIGS. 2A and 2B are diagrams illustrating a semiconductor chip mounting operation (S110) according to an example embodiment. FIG. 2A is a plan view of a substrate 101 on which a semiconductor chip 102 is mounted, and FIG. 2B is a cross-sectional view taken along line I-I′ of FIG. 2A.

Referring to FIGS. 1, 2A, and 2B, the semiconductor chip 102 may be mounted on the substrate 101 (S110).

The substrate 101 may be a package substrate (e.g., a printed circuit board) on which the semiconductor chip 102 is mounted. The substrate 101 may include a lower pad 101P1 electrically connected to an external device, such as a module substrate or a main board, and an upper pad 101P2 electrically connected to the semiconductor chip 102. The lower pad 101P1 and the upper pad 101P2 may be electrically connected through a conductive layer 101M. In other examples, the substrate may be an interposer, a redistribution layer or another semiconductor chip, that forms part of a semiconductor package. The semiconductor chip 102 may be electrically connected to the substrate 101 using a flip-chip method. The connection pad 102P of the semiconductor chip 102 may be connected to the upper pad 101P2 of the substrate 101 through a bump BP. The semiconductor chip 102 may include a logic chip including a central processing unit (CPU), a graphics processing unit (GPU), a field programmable gate array (FPGA), an application processor (AP), a digital signal processor, an encryption processor, a microprocessor, a microcontroller, and analog-to-digital converter, an application-specific integrated chip (ASIC) and/or a memory chip including volatile memory, such as dynamic RAM (DRAM) and static RAM (SRAM), and non-volatile memory, such as phase change RAM (PRAM), magnetic RAM (MRAM), and resistive RAM (RRAM).

The bump BP may include a low melting point metal, for example, tin (Sn) or an alloy including tin (Sn) (e.g., Sn—Ag—Cu, Sn—Ag, etc.). According to an embodiment, the bump BP may have a form of a combination of a pillar and a ball.

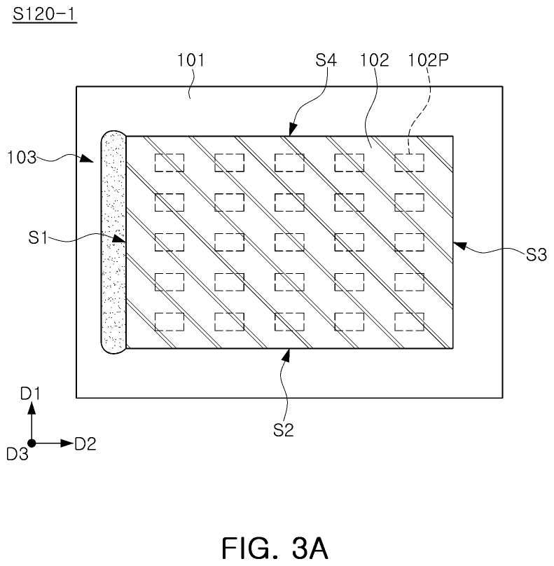

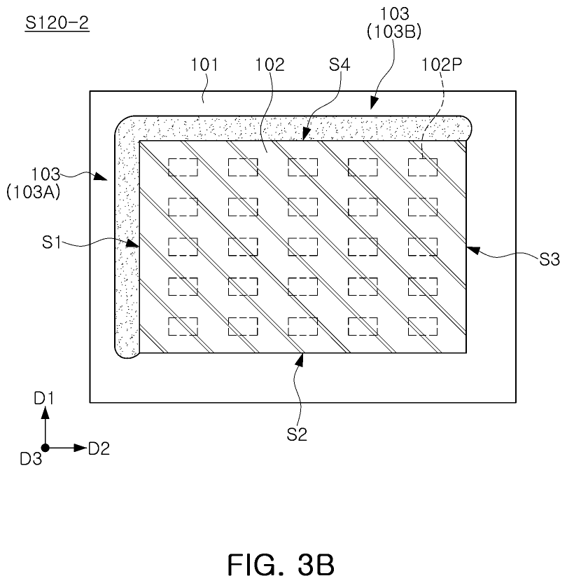

FIGS. 3A and 3B are diagrams illustrating operations (S120-1 and S120-2) of dispensing the resin composition 103 according to an example embodiment. FIGS. 3A and 3B are plan views of the substrate 101 on which the resin composition 103 is dispensed, respectively, according to an example embodiment.

Referring to FIGS. 1, 3A, and 3B, in the operations (S120-1 and S120-2) of dispensing the resin composition 103 of an example embodiment, the resin composition 103 may be dispensed to at least the first side of the semiconductor chip 102. The resin composition 103 may fill the space between the connection pads 102P of the semiconductor chip 102 and have a low viscosity, suitable such that it may flow between the semiconductor chip 102 and the substrate 101 by capillary action, e.g., 50 mPa·s to 1,000 mPa·s (based on 100° C.).

As shown in FIG. 3A, in the operation (S120-1) of dispensing the resin composition 103, the resin composition 103 may be dispensed to the first side of the semiconductor chip 102. For example, the resin composition 103 may be dispensed to a location adjacent to a first side surface S1, among the first side surface S1, a second side surface S2, a third side surface S3, and a fourth side surface S4 of the semiconductor chip 102.

As shown in FIG. 3B, in the operation (S120-2) of dispensing the resin composition 103, the resin composition 103 may be dispensed to both sides of the semiconductor chip 102. For example, the resin composition 103 may be dispensed to locations adjacent to the first side surface S1 and the fourth side surface S4, among the first side surface S1, the second side surface S2, the third side surface S3, and the fourth side surface S4 of the semiconductor chip 102. The resin composition 103 may include a first dispensing portion 103A which may be dispensed to a location adjacent to the first side surface S1 and a second dispensing portion 103B which may be dispensed to a location adjacent to the fourth side surface S4 as depicted for example, in FIG. 3B, or the second dispensing portion may be dispensed to a location adjacent to the second side surface (not shown).

In this manner, the location to which the resin composition 103 is dispensed may vary according to an embodiment. For example, the resin composition 103 may be dispensed to a portion of the first side surface S1 and/or a portion of the fourth side surface S4.

FIGS. 4A and 4B are diagrams illustrating an operation (S130-1a) of projecting infrared light 104 according to an example embodiment. FIG. 4A is a plan view of the substrate 101 onto which the infrared light 104 is projected according to an example embodiment, and FIG. 4B is a cross-sectional view taken along line II-II′ of FIG. 4A.

Referring to FIGS. 1, 4A, and 4B, in the operation (S130-1a) of projecting the infrared light 104 of an example embodiment, the infrared light 104 may be projected onto at least a portion of a fillet portion 103b2 of the resin composition 103 flowing to the outside of the semiconductor chip 102.

It is described herein that IR light is projected onto at least a portion of the fillet portion of the resin composition while the resin composition flows to an opposite side of the semiconductor chip from the first side. The time period during which IR light is projected and during which the resin composition is flowing does not need to overlap 100%. For example, the resin composition may start flowing from a first side to the opposite side of the chip prior to the IR light starting to be projected. It is also contemplated that the IR light may continue projecting after the flow has completed. Various embodiments of time overlap between the two actions are included and encompassed herein by the term “while”. According to example embodiments, in FIG. 1, steps S120 and S130 may overlap in time, with the IR light being projected while resin composition continues to be dispensed.

The resin composition 103 may include a filling portion 103a flowing between the substrate 101 and the semiconductor chip 102 and a fillet portion 103b flowing around the semiconductor chip 102. It may be understood that the filling portion 103a of the resin composition 103 flows in an inside region of the semiconductor chip 101 and the fillet portion 103b flows in an outside region of the semiconductor chip 102.

In an embodiment (S130-1a), the outside or fillet portion 103 may include a first fillet portion (or first outside portion) 103b1 extending on the first side surface S1 of the semiconductor chip 102 in a first direction D1 and a second fillet portion (or second outside portion) 103b2 extending on the second side surface S2 and the fourth side surface S4 of the semiconductor chip 102 in a second direction D2, intersecting the first direction D1, and the infrared light 104 may be projected onto the second fillet portion 103b2. The second fillet portion 103b2 may extend integrally with the first fillet portion 103b1.

As the temperature of the second fillet portion 103b2 onto which the infrared light 104 is projected increases to be higher than the temperature of each of the first fillet portion 103b1 and the filling portion 103a, the viscosity of the second fillet portion 103b2 may increase to be higher than the viscosity of the first fillet portion 103b1 and the viscosity of the filling portion 103a and the flow of the second fillet portion 103b2 may be controlled. Therefore, a first width d1 of the first fillet portion 103b1 in a direction (e.g., the direction D2), extending away from, or perpendicular to, the side surface S1 of the semiconductor chip 102 adjacent to the first fillet portion 103b1, may be greater than a second width d2 of the second fillet portion 103b2 in a direction (e.g., the direction D1), expending away from, or perpendicular to, the side surfaces S2 and S4 of the semiconductor chip 102 adjacent to the portion 103b2. In addition, as the flow of the resin composition 103 toward the outside of the semiconductor chip 102 is suppressed, the filling properties of the resin composition 103 inside the semiconductor chip 102 may be improved.

The infrared light 104 may be projected by an infrared light source 10. The infrared light source 10 may include a laser, a lamp, etc. The infrared light 104 may be closest to or in contact with the second side surface S2 and the fourth side surface S4 of the semiconductor chip 102 to illuminate the entire second fillet portion 103b2, but is not limited thereto. In FIG. 4A, the infrared light 104 is shown as an area including both regions corresponding to the second side surface S2 and the fourth side surface S4 of the semiconductor chip 102, but is not limited thereto. When the infrared light 104 is projected to an area smaller than that shown, the infrared light source 10 may project the infrared light 104 to the second fillet portion 130b2, while moving along the flow of the second fillet portion 103b2 or moving along the side surface of the semiconductor chip 102.

A time for which the infrared light 104 is projected may be shorter than a curing time of the resin composition 103, which is described below. In an example embodiment, the operation (S130) of projecting the infrared light 104 may be performed so that the fillet portion (e.g., the second fillet portion 103b2) onto which the ray is projected is not completely cured. If the fillet portion (e.g., the second fillet portion 103b2) onto which the infrared light 104 is projected is completely cured, the temperature and viscosity of the filling portion 103a may increase and the filling properties of the resin composition 103 may deteriorate.

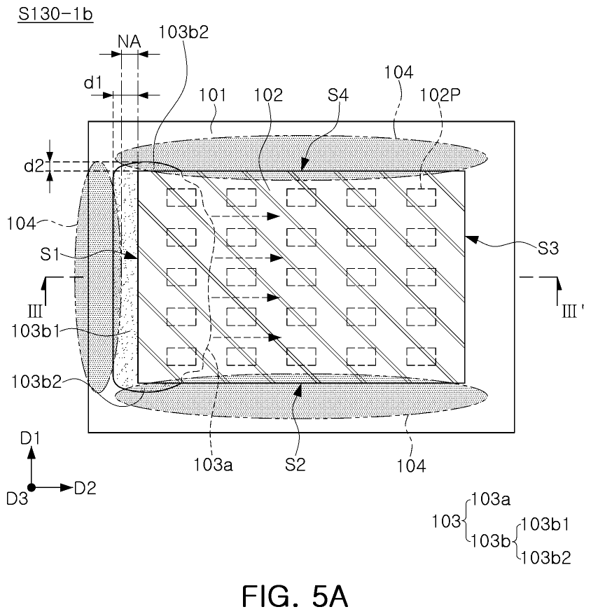

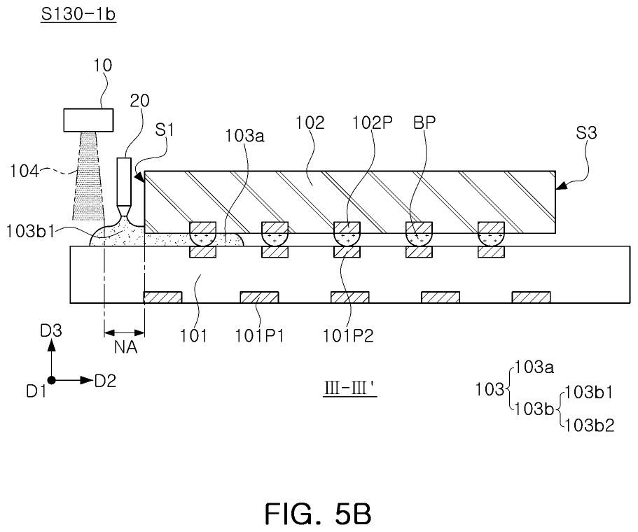

FIGS. 5A and 5B are diagrams illustrating an operation (S130-1b) of projecting the infrared light 104 according to an example embodiment. FIG. 5A is a plan view of the substrate 101 onto which the infrared light 104 is projected according to an example embodiment, and FIG. 5B is a cross-sectional view taken along line III-III′ of FIG. 5A.

Referring to FIGS. 1, 5A, and 5B, in the operation (S130-1b) of projecting the infrared light 104 of an example embodiment, the infrared light 104 may be projected to the first side (e.g., a peripheral region of the first side surface S1) of the semiconductor chip 102 on which the resin composition 103 is dispensed. For example, the infrared light 104 may be further projected onto at least a portion of the first fillet portion 103b1. When the infrared light 104 is projected to an area smaller than that shown, the infrared light source 10 may project the infrared light 104 onto the first fillet portion 103b1, while moving along the flow of the first fillet portion 103b1 or while moving along the first side surface S2 of the semiconductor chip 102.

As shown in FIG. 5B, in an embodiment (S130-1b), a dispenser 20 may be configured to dispense the resin composition 103 to an underfill supply region NA adjacent to the first side surface S1 of the semiconductor chip 102. To prevent the viscosity of the resin composition 103 located in the underfill supply region NA from increasing, the infrared light 104 may be spaced apart from the first side surface S1 of the semiconductor chip 102. A distance between the infrared light 104 and the first side surface S1 of the semiconductor chip 102 may be determined according to characteristics of the resin composition 103 and the characteristics of the infrared light 104.

The temperature of a portion of the first fillet portion 103b1 onto which the infrared light 104 is projected may be higher than the temperature of the other portions of the first fillet portion 103b1 in the underfill supply region NA. Accordingly, the viscosity of the first fillet portion 103b1 in the underfill supply region NA may increase. That is, the infrared light 104 may suppress the flow of the first fillet portion 103b1 beyond the underfill supply region NA. Due to the underfill supply region NA in which the infrared light 104 is not projected, the first width d1 of the first fillet portion 103b1 may be larger than the second width d2 of the second fillet portion 103b2.

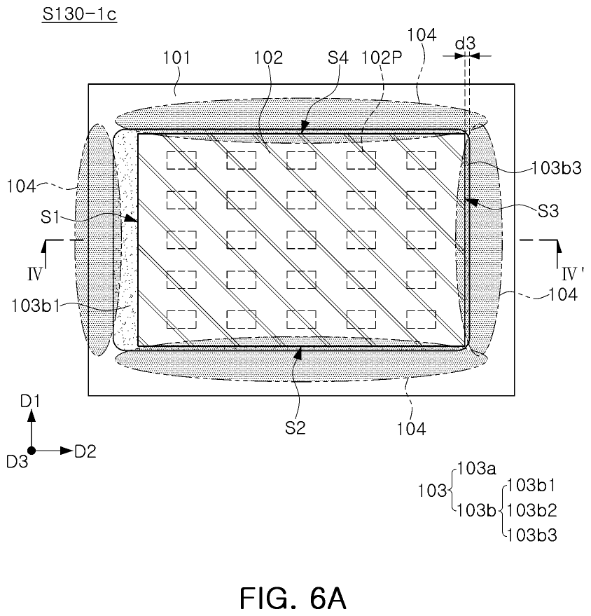

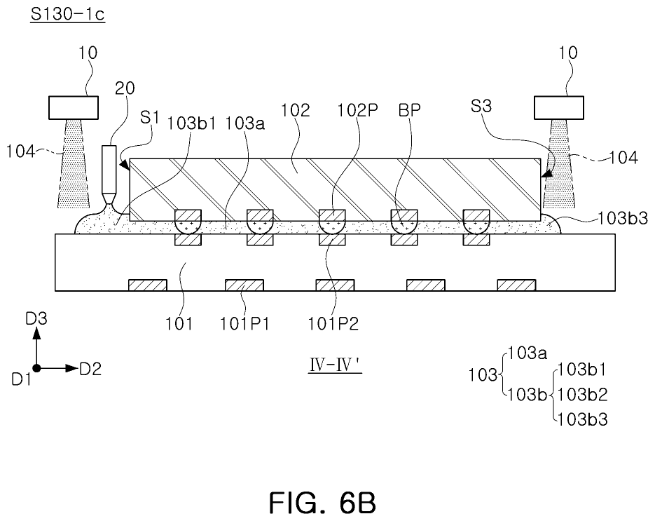

FIGS. 6A and 6B are diagrams illustrating an operation (S130-1c) of projecting infrared light according to an example embodiment. FIG. 6A is a plan view of the substrate 101 onto which the infrared light 104 is projected according to an example embodiment, and FIG. 6B is a cross-sectional view taken along line IV-IV′ of FIG. 6A.

Referring to FIGS. 1, 6A, and 6B, in the operation (S130-1c) of projecting the infrared light 104 of an example embodiment, the infrared light 104 may be projected onto a third fillet portion (or third outside portion) 103b3 in which the dispensed resin composition 103 flows to the other side (e.g., the peripheral region of the third side surface S3) opposite to the first side (e.g., the peripheral region of the first side surface S1).

In an embodiment (S130-1c), the fillet portion 103 may include a first fillet portion 103b1 extending on the first side surface S1 of the semiconductor chip 102 in the first direction D1, a second fillet portion 103b2 extending on the second side surface S2 and the fourth side surface S4 of the semiconductor chip 102 in the second direction D2, intersecting the first direction D1, and third fillet portion 103b3 extending on the third side surface S3 of the semiconductor chip 102 in the first direction D1.

The infrared light 104 may be projected for example, onto all of the first fillet portion 103b1, the second fillet portion 103b2, and the third fillet portion 103b3, or onto portions thereof. The first fillet portion 103b1, the second fillet portion 103b2, and the third fillet portion 103b3 may extend integrally. As the temperature of the third fillet portion 103b3 onto which the infrared light 104 is projected increases to be higher than the temperature of the filling portion 103a, the viscosity of the third fillet portion 103b3 increases and the flow thereof may be controlled. Accordingly, a third width d3 of the third fillet portion 103b3 may be smaller than the first width d1 of the first fillet portion 103b1.

When the infrared light 104 is projected to an area smaller than that shown, the infrared light source 10 may project the infrared light 104 to the third fillet portion 103b3, while moving along the flow of the third fillet portion 103b3 or while moving along the third side surface S3 of the semiconductor chip 102. In FIG. 6A, the infrared light 104 is projected onto all the first fillet portion 103b1, the second fillet portion 103b2, the third fillet portion 103b3, and the fourth fillet portion 103b4, but according to an example embodiment, the infrared light 104 may be projected onto the second fillet portion and the third fillet portion, but not projected onto the first fillet portion 103b1.

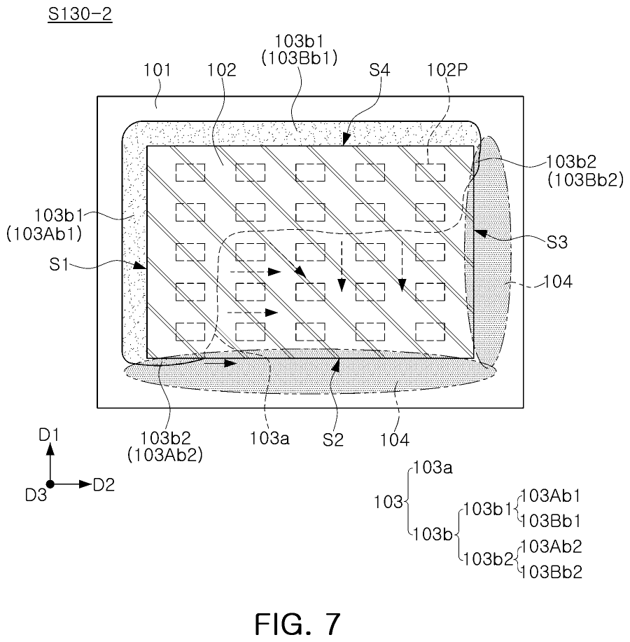

FIG. 7 is a diagram illustrating an operation (S130-2) of projecting the infrared light 104 according to an example embodiment. FIG. 7 is a plan view of the substrate 101 onto which the infrared light 104 is projected according to an example embodiment.

Referring to FIGS. 1 and 7, in the operation (S130-2) of projecting the infrared light 104 of an example embodiment, the resin composition 103 may be dispensed on at least both sides of the semiconductor chip 102. For example, the resin composition 103 may be dispensed to the periphery of the first side surface S1 and the fourth side surface S4 of the semiconductor chip 102.

In an embodiment (S130-2), the fillet portion 103b may include a first fillet portion 103b1 adjacent to the first side surface S1 and the fourth side surface S4 and a second fillet portion 103b2 adjacent to the second side surface S2 and the third side surface S3.

The first fillet portion 103b1 may include a first portion 103Ab1 adjacent to the first side surface S1 and a second portion 103Bb1 adjacent to the fourth side surface S4. The first portion 103Ab1 of the first fillet portion 103b1 may extend in the first direction D1, and the second portion 103Bb1 of the first fillet portion 103b1 may extend in the second direction D2.

The second fillet portion 103b2 may include a first portion 103Ab2 of the second fillet portion 103b2 extending in the second direction D2, intersecting the first portion 103Ab1 of the first fillet portion 103b1, and a second portion 103Bb2 of the second fillet portion 103b2 extending in the first direction D1, intersecting the second portion 103Bb1 of the first fillet portion 103b1.

The infrared light 104 may be projected onto the first portion 103Ab2 of the second fillet portion 103b2 and the second portion 103Bb2 of the second fillet portion 103b2. As the temperature of each of the first portion 103Ab2 of the second fillet portion 103b2 and the second portion 103Bb2 of the second fillet portion 103b2, onto which the infrared light 104 is projected, is increased to be higher than the temperature of each of the first portion 103Ab1 of the first fillet portion 103b1, the second portion 103Bb1 of the first fillet portion 103b1, and the filling portion 103a, the viscosity of the second fillet portion 103b2 may increase and the flow of the second fillet portion 103b2 may be controlled.

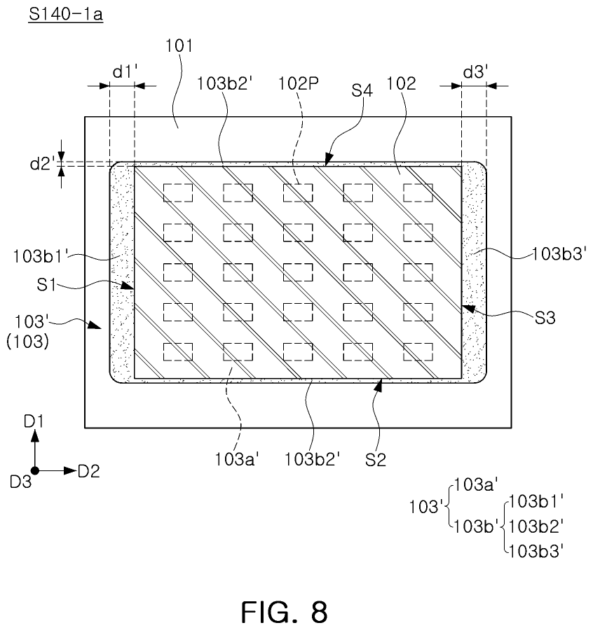

FIGS. 8 to 10 are diagrams illustrating operations (S140-1a, S140-1b, and S140-2) of curing a resin composition according to example embodiments. FIGS. 8 to 10 illustrate a cured underfill resin layer 103′ after undergoing the operation of projecting the infrared light 104 of FIGS. 4A, 6A, and 7, respectively. FIGS. 8 to 10 are plan views of the substrate 101 on which the underfill resin layer 103′ is formed.

Referring to FIGS. 1, 8, 9, and 10, the operations (S140-1a, S140-1b, and S140-2) of curing a resin composition may be performed until the resin composition 103 is completely cured, after flowing from the first side (e.g., the peripheral region of the first side surface S1) of the semiconductor chip 102 to the other side (e.g., the peripheral region of the third side surface S3), which is the opposite side. The operation of curing the resin composition 103 may be performed in a temperature atmosphere having a temperature of 150° C. or higher. The underfill resin layer 103,′ in which the resin composition 103 is cured, may include an internal portion 103a′ disposed on an inside region of the semiconductor chip and filling a space between the substrate 101 and the semiconductor chip 102 and an external portion 103b′ extending from the internal portion 103a′ to protrude to the outside of the semiconductor chip 102.

As shown in FIG. 8, the underfill resin layer 103′ formed by the curing operation (S140-1a) of an example embodiment may include a first external portion 103b1′ extending on the first side surface S1 of the semiconductor chip 102 in the first direction D1, a second external portion 103b2′ extending on the second side surface S2 and the fourth side surface S4 of the semiconductor chip 102 in the second direction D2, and a third external portion 103b3′ extending on the third side surface S3 of the semiconductor chip 102 in the first direction D1. The second external portion 103b2′ may correspond to a fillet portion in which infrared light is projected and the flow in an outward direction is suppressed. Accordingly, a second width d2′ of the second external portion 103b2′ may be smaller than a first width d1′ of the first external portion 103bl′ and a third width d3′ of the third external portion 103b3′.

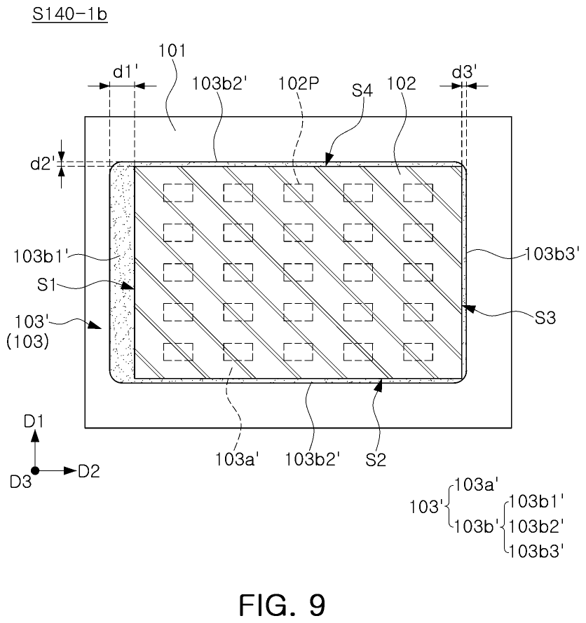

As shown in FIG. 9, the underfill resin layer 103′ formed by the curing operation (S140-1b) of an example embodiment may include a first external portion 103b1′ adjacent to the first side surface S1 of the semiconductor chip 102, a second external portion 103b2′ adjacent to the second side surface S2 and the fourth side surface S4 of the semiconductor chip 102, and a third external portion 103b3′ adjacent to the third side surface S3 of the semiconductor chip 102. The second external portion 103b2′ and the third external portion 103b3′ may correspond to a fillet portion to which infrared light is projected and the flow of the resin composition in the outward direction is suppressed. Accordingly, the second width d2′ of the second external portion 103b2′ and the third width d3′ of the third external portion 103b3′ may be smaller than the first width d1′ of the first external portion 103b1′.

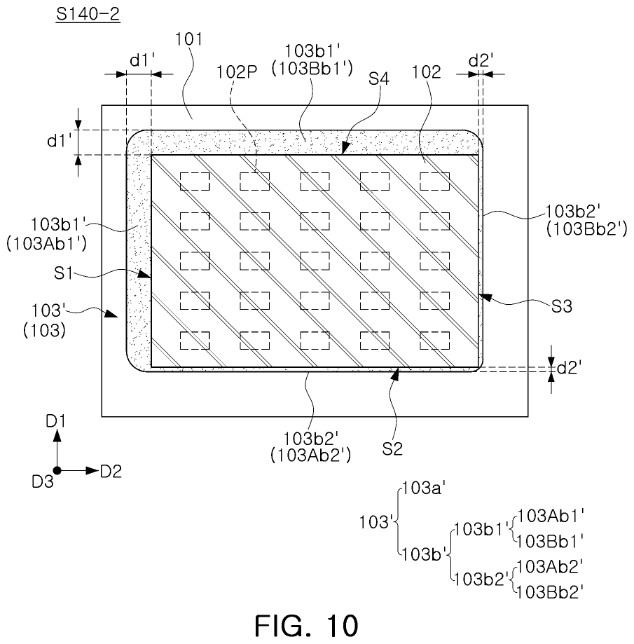

As shown in FIG. 10, the underfill resin layer 103′ formed by the curing operation (S140-2) of an example embodiment may include a first external portion 103b1′ adjacent to the first side surface S1 and the fourth side surface S4 and a second external portion 103b2′ adjacent to the second side surface S2 and the third side surface S3.

The first external portion 103b1′ may include a first portion 103Ab1′ adjacent to the first side surface S1 and a second portion 103Bb1′ adjacent to the fourth side surface S4. The first portion 103Ab1′ of the first external portion 103b1′ may extend in the first direction D1, and the second portion 103Bb1′ of the first external portion 103b1′ may extend in the second direction D2.

The second external portion 103b2′ may include a first portion 103Ab2′ extending in the second direction D2, intersecting the first portion 103Ab1 of the first external portion 103b1,′ and a second portion 103Bb2′ extending in the first direction D1, intersecting the second portion 103Bb1′ of the first external portion 103b1′.

The first portion 103Ab2′ and the second portion 103Bb2′ of the second external portion 103b2′ may correspond to a fillet portion in which infrared light is projected and the flow of the resin composition in the outward direction is suppressed. Accordingly, the second width d2′ of each of the first portion 103Ab2′ and the second portion 103Bb2′ of the second external portion 103b2′ may be smaller than the first width d1′ of each of the first portion Ab1′ and the second portion 103Bb1′ of the first external portion 103b1′.

According to example embodiments, in FIG. 1, steps S130 of projecting IR light and S140 (curing resin composition) may overlap in time, with the IR light being projected while resin composition is cured. Additionally, according to example embodiments that include curing, the infrared light may be projected for a shorter time than a time for which the resin composition is cured.

According to embodiments of the present inventive concept, a resin composition having viscosity increasing in a partial region in which infrared light is absorbed, may be provided.

In addition, according to embodiments of the present inventive concept, a method of forming underfill or method of manufacturing a semiconductor package with improved reliability may be provided by introducing the operation of locally controlling the flow of the resin composition.

While example embodiments have been shown and described above, it will be apparent to those skilled in the art that modifications and variations could be made without departing from the scope of the present inventive concept as defined by the appended claims.

What is claimed is:

1. A method of manufacturing a semiconductor package, comprising:
mounting a semiconductor chip on a substrate;
dispensing a resin composition to a first side of the semiconductor chip, wherein the resin composition includes a filling portion flowing to an inside region of the semiconductor chip between the semiconductor chip and the substrate, and an outside portion flowing to a region outside of the semiconductor chip; and
projecting infrared light onto at least a portion of the outside portion of the resin composition, while the resin composition flows to an opposite side of the semiconductor chip that is opposite from the first side of the semiconductor chip,
wherein the resin composition includes
20 to 40 wt % of an epoxy resin;
5 to 10 wt % of a curing agent;
50 to 70 wt % of a filler; and
1 to 5 wt % of an infrared absorber.

2. The method of claim 1, wherein
the outside portion includes a first outside portion extending in a first direction extending from a first side surface of the first side of the semiconductor chip and a second outside portion extending in a second direction from a second side of the semiconductor chip, the second direction intersecting the first direction, and
the infrared light is projected onto the second outside portion.

3. The method of claim 2, wherein a first width of the first outside portion extending away from the first side surface of the semiconductor chip adjacent to the first outside portion is greater than a second width of the second outside portion extending away from a second side surface of the semiconductor chip adjacent to the second outside portion.

4. The method of claim 2, wherein
the outside portion further includes a third outside portion on the opposite side of the semiconductor chip extending in the first direction from the first outside portion,
the infrared light is projected onto the second outside portion and the third outside portion,
a first width of the first outside portion extending away from the first side surface of the semiconductor chip adjacent to the first outside portion is greater than a second width of the second outside portion extending away from a second side surface of the semiconductor chip adjacent to the second outside portion, and a third width of the third outside portion extending away from a third side surface of the semiconductor chip adjacent to the third outside portion.

5. The method of claim 2, wherein the infrared light is further projected onto at least a portion of the first outside portion.

6. The method of claim 1, wherein after infrared light is projected onto at least a portion of the outside portion, a first temperature of the outside portion is higher than a second temperature of the filling portion.

7. The method of claim 6, wherein a viscosity of the outside portion onto which the infrared light is projected is higher than a viscosity of the filling portion.

8. The method of claim 1, further comprising curing the resin composition, after the resin composition flows to the opposite side of the semiconductor chip, to form an underfill resin layer.

9. The method of claim 8, wherein the underfill resin layer includes an internal portion disposed on the inside region of the semiconductor chip and an external portion extending from the internal portion and disposed on the outside region of the semiconductor chip.

10. The method of claim 8, wherein the infrared light is projected for a shorter time than a time for which the resin composition is cured.

11. The method of claim 1, wherein the infrared absorber includes a compound having at least one structure selected from the group consisting of Chemical formula 1, Chemical formula 2, Chemical formula 3, and Chemical formula 4: 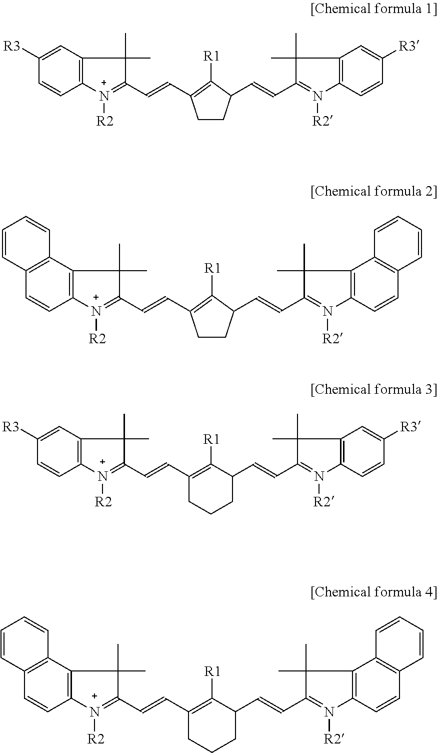
wherein R1 includes a barbiturate group,
R2 and R2′ include at least one group selected from the group consisting of a methyl group, an ethyl group, and a 3-methylbutyl group, and
R3 and R3′ include hydrogen or chlorine.

12. The method of claim 1, wherein the epoxy resin includes at least one epoxy component selected from the group consisting of a bisphenol-A epoxy, a bisphenol-F epoxy, rubber modified epoxy, novolac epoxy, cycloaliphatic epoxy, tetra-functional epoxy, acryl modified epoxy, coal tar modified epoxy, aliphatic chain modified epoxy, cresol novolac epoxy, polyglycol epoxy, cardanol epoxy, brominated epoxy, and phenoxy epoxy.

13. The method of claim 1, wherein the curing agent includes at least one curing agent selected from the group consisting of an acid anhydride-based curing agent, a cationic curing agent, an imidazole curing agent, a dicyandiamide curing agent, and an amine adduct curing agent.

14. The method of claim 1, wherein the filler includes fused silica or synthetic silica.

15. A method of manufacturing a semiconductor package, comprising:
mounting a semiconductor chip on a substrate;
dispensing a resin composition including an infrared absorber to a first side of the semiconductor chip, wherein the resin composition includes a filling portion flowing to an inside region of the semiconductor chip between the semiconductor chip and the substrate, and an outside portion flowing to a region outside of the semiconductor chip; and
projecting infrared light onto at least a portion of the resin composition, while the resin composition flows between the semiconductor chip and the substrate from the first side of the semiconductor chip,
wherein the outside portion includes a first outside portion adjacent to a first side surface of the semiconductor chip corresponding to the first side of the semiconductor chip, and a second outside portion adjacent to a second side surface of the semiconductor chip, intersecting the first side surface,
wherein the infrared light is projected onto the second outside portion, and
wherein a second width of the second outside portion is smaller than a first width of the first outside portion.

16. The method of claim 15, wherein
the infrared light is further projected onto a portion of the first outside portion, and
the infrared light projected onto a portion of the first outside portion is spaced apart from the first side surface of the semiconductor chip.

17. The method of claim 15, wherein the infrared absorber includes a compound having a heptamethine cyanine structure.

18. The method of claim 15, wherein
the outside portion further includes a third outside portion adjacent to a third side surface of the semiconductor chip, intersecting the second side surface,
the infrared light is further projected onto the third outside portion, and
a third width of the third outside portion is smaller than the first width of the first outside portion.

19. A resin composition comprising:
20 to 40 wt % of an epoxy resin;
5 to 10 wt % of a curing agent;
50 to 70 wt % of a filler; and
1 to 5 wt % of an infrared absorber including a compound having at least one structure selected from the group consisting of Chemical formula 1, Chemical formula 2, Chemical formula 3, and Chemical formula 4 below, 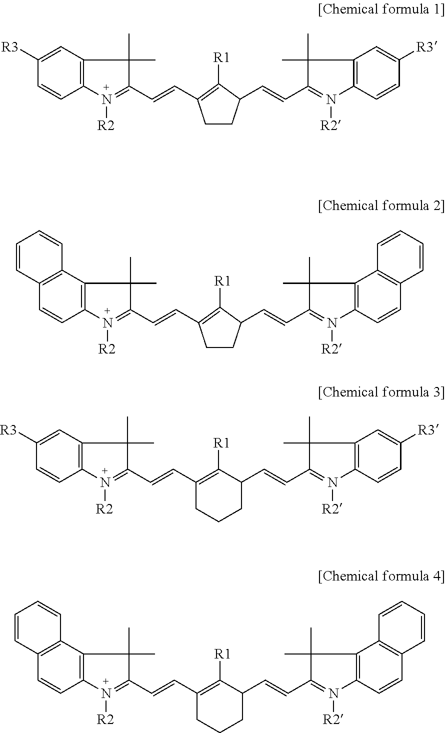
wherein R1 includes a barbiturate group,
R2 and R2′ include at least one group selected from the group consisting of a methyl group, an ethyl group, and a 3-methylbutyl group, and
R3 and R3′ include hydrogen or chlorine.

20. The resin composition of claim 19, wherein the infrared absorber is capable of absorbing light having a wavelength ranging from 700 nm to 1200 nm and converting the absorbed light into thermal energy.
